(19) United States
(12) Patent Application Publication
(10) Pub. No.: US 2012/0248599 A1
(43) Pub. Date: Oct. 4, 2012

(54) RELIABLE SOLDER BUMP COUPLING WITHIN A CHIP SCALE PACKAGE

(76) Inventor: Matthew A. Ring, Saco, ME (US)

(21) Appl. No.: 13/426,338

(22) Filed: Mar. 21, 2012

Related U.S. Application Data
(60) Provisional application No. 61/468,241, filed on Mar. 28, 2011.

(51) Int. Cl. H01L 23/498; H01L 21/60

(52) U.S. Cl. 257/737; 438/613; 257/E23.068; 257/E21.508

(57) ABSTRACT

In one general aspect, an apparatus can include a semiconductor substrate including at least one semiconductor device, and a metal layer disposed on the semiconductor substrate. The apparatus can include a nonconductive layer defining an opening and having a cross-sectional portion of the nonconductive layer defining a protrusion disposed over a recess in the metal layer, and can include a solder bump having a portion disposed between the metal layer and the protrusion defined by the nonconductive layer.

### RELATED APPLICATIONS

This application claims priority to and the benefit of U.S. Provisional Patent Application Ser. No. 61/468,241, filed on Mar. 28, 2011, entitled, “Reliable Solder Bump Coupling within a Chip Scale Package,” which is incorporated herein by reference in its entirety.

### TECHNICAL FIELD

This description relates to a reliable solder bump coupling within a chip scale package.

### BACKGROUND

Reliability of coupling (e.g., joint) of solder bumps within a wafer-level chip scale package (WLCSP) of a semiconductor device is a critical issue during fabrication of the WLCSP assembly. An unreliable coupling between the solder bumps and the rest of the wafer-level chip scale package can result in a failure (e.g., a mechanical failure, an electronic failure) of the WLCSP during reliability testing and/or during use of the WLCSP in a computing application. For example, some known solder bump configurations within a WLCSP are prone to cracking at an undesirable rate during reliability testing and/or during use of the solder bump of the WLCSP. For example, a reliability test, such as a board-level drop test, can cause a solder bump to lift away from a bond pad and/or crack in an undesirable fashion at the corners of the solder bump at a junction between an opening of the encapsulation layer (e.g., a polyimide layer) and the bond pad below where the solder bump is joined. Thus, a need exists for methods and apparatus to address the shortfalls of present technology and to provide other new and innovative features.

### SUMMARY

In one general aspect, an apparatus can include a semiconductor substrate including at least one semiconductor device, and a metal layer disposed on the semiconductor substrate. The apparatus can include a nonconductive layer defining an opening and having a cross-sectional portion of the nonconductive layer defining a protrusion disposed over a recess in the metal layer, and can include a solder bump having a portion disposed between the metal layer and the protrusion defined by the nonconductive layer.

In another general aspect, a method can include forming a metal layer on a semiconductor substrate, and forming, on the metal layer, a nonconductive layer including an opening. The method can include defining at least a portion of a cavity aligned within the opening and in the metal layer below the nonconductive layer. The method can also include disposing at least a portion of a solder bump within the cavity.

In yet another general aspect, an apparatus can include a semiconductor substrate including at least one semiconductor device, and a nonconductive layer defining an opening. The apparatus can include a metal layer disposed between the semiconductor substrate and a nonconductive layer. The metal layer can define a recess having a portion disposed below the opening and having a portion with a width greater than a width of a portion of the opening of the nonconductive layer aligned along an interface between the metal layer and the nonconductive layer.

The details of one or more implementations are set forth in the accompanying drawings and the description below. Other features will be apparent from the description and drawings, and from the claims.

### BRIEF DESCRIPTION OF THE DRAWINGS

FIG. 1A is a cross-sectional diagram that illustrates a solder bump of a portion of a chip scale package, according to an embodiment.

FIG. 1B is a diagram that illustrates a top cross-sectional view of the portion of the chip scale package shown in FIG. 1A.

FIGS. 2A through 2E are cross-sectional diagrams that illustrate a method for producing a portion of a chip scale package.

FIG. 3 is a flowchart that illustrates a method for forming a portion of a chip scale package, according to an embodiment.

FIG. 4 is a scanning electron microscopic (SEM) image of a cross-sectional portion of a chip scale package, according to an embodiment.

FIG. 5 is another SEM image of a cross-sectional portion of a chip scale package, according to an embodiment.

### DETAILED DESCRIPTION

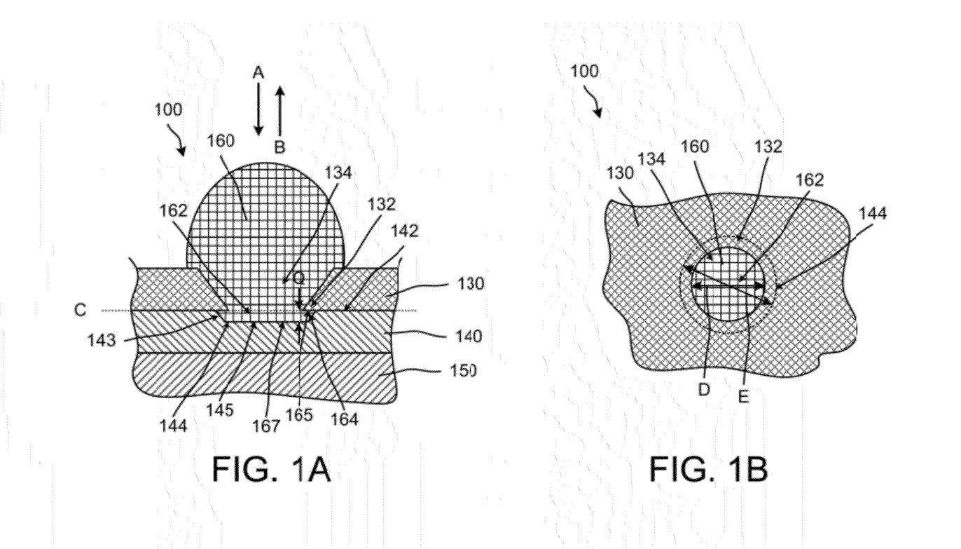

FIG. 1A is a cross-sectional diagram that illustrates a solder bump 160 of a portion of a chip scale package 100 (CSP), according to an embodiment. The portion of the chip scale package 100 shown in FIG. 1 can be a wafer-level chip scale package (WLCSP). The solder bump 160 is coupled to (e.g., in contact with, bonded to) a nonconductive layer 130 (which can also be referred to as an encapsulating layer) and/or an under bump metallization (UBM) layer 140. The UBM layer 140 (which can also be referred to as a conductive layer) is disposed on a semiconductor substrate 150. The semiconductor substrate 150 can include various semiconductor devices and/or features such as transistors (e.g., metal-oxide-semiconductor field effect transistors (MOSFETs), vertical MOSFETs, lateral MOSFETs, bipolar junction transistors (BJTs)), diodes, resistors, inductors, vias, metal layers, and/or so forth.

In several of the embodiments described herein, the terms top and bottom, which correspond with the top and bottom of the figures (when oriented right side up), are used to refer to features (e.g., features of the portion of the chip scale package 100). Because many of the features are mirrored within the portion of the chip scale package 100, for simplicity, numerals are generally shown on only one side of the portion of the chip scale package 100. Also, some of the features shown in the figures herein may not be drawn to scale.

In some embodiments, the UBM layer 140 can be, or can include, various types of metal (or combinations thereof), such as, for example, copper (Cu), gold (Au), aluminum (Al), nickel (Ni), titanium (Ti), vanadium (V), platinum (Pt), and/or so forth. In some embodiments, the UBM layer 140 can include a nonmetallic conductive material such as polysilicon material. In some embodiments, the UBM layer 124 can be, for example, a layer deposited using semiconductor deposition processing techniques (e.g., chemical vapor deposition (CVD) techniques, sub-atmospheric CVD techniques). In some embodiments, the UBM layer 140 can have a thickness of between a fraction of a micrometer (e.g., 0.2 μm, 0.5 μm) and several micrometers (e.g., 1 μm, 3 μm, 10 μm). In some embodiments, the UBM layer 140 can define bond pads (e.g., bond pad areas) to which at least a portion of the solder bump 160 may be coupled. In some embodiments, the UBM layer 140 can include one or more layers that can each include one or more different types of conductive materials.

In some embodiments, the nonconductive layer 130 can be, or can include, for example, polyimide, polybenzobisoxazole (PBO), benzocyclobutene (BCB), silicon dioxide, silicon nitride, and/or so forth. In some embodiments, the nonconductive layer 130 can be, for example, a layer deposited using semiconductor deposition processing techniques and/or can be a photo-defined layer. In some embodiments, the nonconductive layer 130 can have a thickness of between a fraction of a micrometer (e.g., 0.2 μm, 0.5 μm) and several micrometers (e.g., 1 μm, 3 μm, 10 μm, 15 μm, 20 μm).

As shown in FIG. 1A, the solder bump 160 is coupled to the UBM layer 140 through an opening 134 within the nonconductive layer 130. Specifically, the solder bump 160 has a bottom portion 162 disposed within a recess 144 (also can be referred to as a pocket) defined by the UBM layer 140. In some embodiments, the solder bump 160 can be formed using various materials (or combinations thereof) including silver (Ag), tin (Sn), copper (Cu), Nickel (Ni), and/or so forth (e.g., SAC, SNC, SACX, and other tin (Sn) based alloys). In some embodiments, the solder bump 160 may not be coupled to (e.g., may not be in contact with) at least some portions (e.g., upper portions, medial portions) of the nonconductive layer 130.

As shown in FIG. 1A, the recess 144 is defined by a sloped wall 143 (e.g., sidewall) and by a flat (e.g., substantially flat) bottom surface 145. In some embodiments, the recess 144 can be formed within the UBM layer 140 using an etching process such as an isotropic etching process (e.g., a wet etch process) and/or an anisotropic etching process (e.g., reactive ion etching (RIE) process). In some embodiments, the etch process used to produce the recess 144 in the UBM layer 140 can be referred to as an over-etch process because the etching removes material below at least a portion of the nonconductive layer 130.

In some embodiments, the recess 144 can have a different profile (e.g., cross-sectional profile) than shown in FIG. 1A. For example, in some embodiments, the wall 143 of the recess 144 may have a different slope than shown in FIG. 1A. In some embodiments, the wall 143 of the recess 144 can be substantially vertical. In some embodiments, the bottom of the recess 144 can be curved (e.g., concave up, concave down), can be flat, can have sloping portions, and/or so forth.

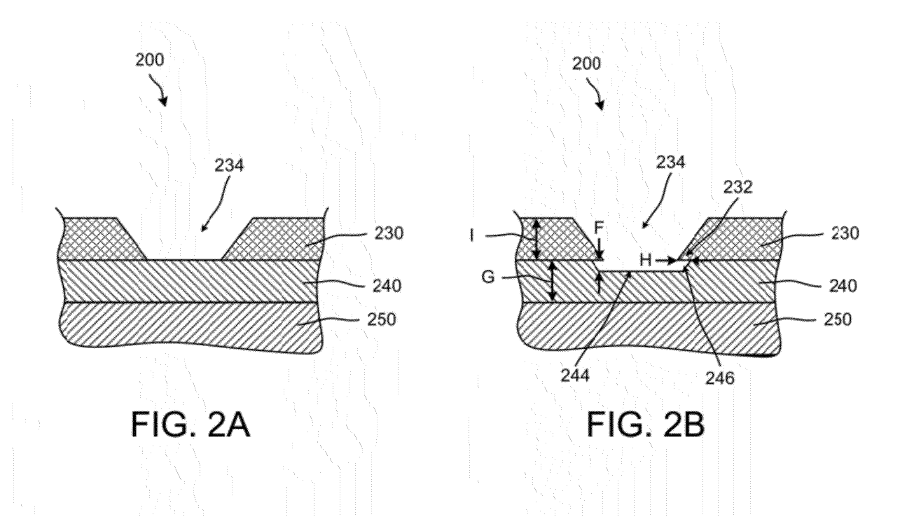

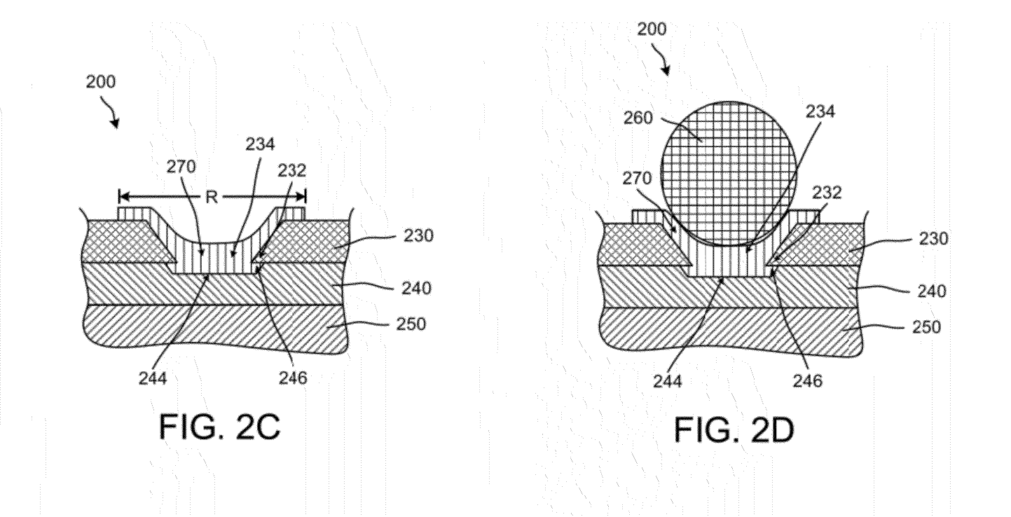

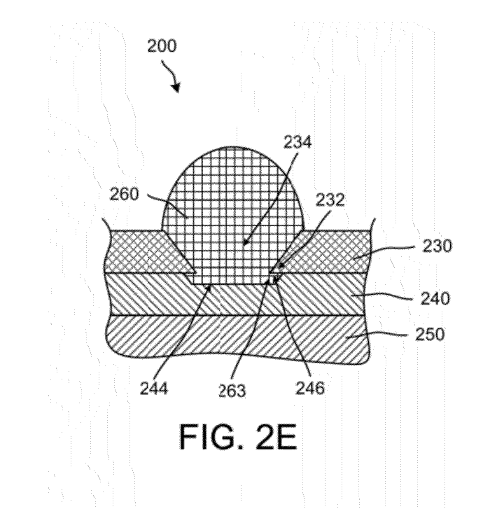

As shown in FIG. 1A, a protrusion 132 defined by the nonconductive layer 130 is aligned along an interface 142 between the nonconductive layer 130 and the UBM layer 140. The interface 142 is aligned along a plane C. In some embodiments, the protrusion 132 of the nonconductive layer 130 can be referred to as an overhang. The protrusion 132 can be formed as portions of the UBM layer 140 below the protrusion are etched away (e.g., etched away using an isotropic etching process) from underneath the protrusion. More details related to the formation of the protrusion are described below and in connection with, for example, FIGS. 2A through 5.

In this embodiment, the protrusion 132 and the recess 144 collectively define a cavity 164 (or crevice). Specifically, the wall 143 of the recess 144 and a bottom surface of the protrusion 132 collectively define at least a portion of the cavity 164. A portion of the bottom portion 162 of the solder bump 160 within the recess 144 is disposed within the cavity 164. The portion of the bottom portion 162 has an upper surface that is coupled to (or in contact with) a bottom surface of the protrusion 132. In some embodiments, the portion of the bottom portion 162 of the solder bump 160 can be disposed within the cavity 164 during a reflow process of the solder bump 160. The reflow process can include heating of the solder bump 160 until at least a portion of the solder bump 160 melts. More details related to the formation of the solder bump within the cavity 164 are described below and in connection with, for example, FIGS. 2A through 5.

The protrusion 132 of the nonconductive layer 130 can function as a retention member configured to hold the solder bump 160 fast (without lifting away) within the portion of the chip scale package 100. In some embodiments, the protrusion 132 of the nonconductive layer 130 can function as retention member during reliability testing (e.g., stress testing) of the solder bump 160 (and/or the portion of the chip scale package 100) and/or for reliability when the portion of the chip scale package 100 is being used in, for example, a computing application.

For example, the protrusion 132 can prevent (or substantially prevent) the solder bump 160 from cracking (within the solder bump 160), or becoming decoupled from the portion of the chip scale package 100 (e.g., the UBM layer 140 and/or the nonconductive layer 130) during a board-level drop test (BLDT). During a board-level drop test, downward forces (along direction A) can be applied against the solder bump 160 (using an object), which can cause or result in rebound forces (e.g., spring-back forces) in an upward direction (along direction B). The rebound forces can cause the solder bump 160, or a portion thereof, to crack and/or lift away (along direction B) from the metal layer 140. The protrusion 132 can hold the solder bump 160 securely and can prevent the solder bump 160 from cracking and/or lifting away in response to the upward forces (along direction B). This example mechanism should not be considered a limiting example because many possible failure mechanisms can be prevented, or substantially prevented, using the techniques described herein.

Without the formation of the recess 144, which results in the formation of the protrusion 132, the UBM layer 140 would not have the bottom surface 145 disposed within the recess 144, which is disposed below the plane C. Instead, in a non-recessed UBM layer, a bottom edge of a solder bump would terminate at a junction (e.g., an intersection) between the UBM layer (which is not recessed and would be entirely (or substantially) flat along a plane) and a nonconductive layer, and a protrusion would not exist. In such non-recessed configurations, during reliability testing, the solder bump can crack starting at the junction in response to downward forces and subsequent upward forces. This example mechanism should not be considered a limiting example because many possible failure mechanisms can be prevented, or substantially prevented, using the techniques described herein.

A junction (e.g., an intersection) as described in a non-recessed configuration is excluded from the configuration shown in FIG. 1A. Instead, a bottom surface 167 of the solder bump 160, which is along the bottom surface 145 of the recess 144, terminates at the wall 143 of the recess 144, which is made of the same material as the recess 144. The portion of the bottom portion 162 of the solder bump 160 has a point in the upper corner of the cavity 164 that terminates at a junction (e.g., an intersection) between the nonconductive layer 130 and the metal layer 140. However, this junction (e.g., intersection) is below the protrusion 132. Thus, cracking at the junction in response to downward forces (along direction A) and/or subsequent upward forces (along direction B) can be prevented (or substantially prevented). Forces (e.g., force vectors) that would otherwise be distributed within or directed within the solder bump 160 and can cause cracking within the solder bump 160 in a non-recessed configuration, can instead be applied against the protrusion 132 of the nonconductive layer 130 to prevent cracking within the solder bump 160 of the portion of the chip scale package 100 configuration shown in FIG. 1A. In other words, the protrusion 132 can be configured to prevent or substantially prevent failures during reliability testing (and/or use of the portion of the chip scale package 100 within a computing application) by changing the application of forces within (or against) solder bump 160. Said differently, some forces will be applied against the protrusion 132 of the nonconductive layer 130, and distributed elsewhere within the nonconductive layer 130 and/or UBM layer 140, instead of within the solder bump 160. This example mechanism should not be considered a limiting example because many possible failure mechanisms can be prevented, or substantially prevented, using the techniques described herein.

With the formation of the recess 144, the surface area against which the bottom portion 162 of the solder bump 160 may be coupled is also greater than the surface area against which a solder bump 160 may be coupled without formation of the recess 144. Also, the surface area against which forces (e.g., force is applied during a reliability tests) can be applied (and spread out) is also greater with the formation of the recess 144 compared with the surface area of an un-recessed chip scale package configuration (not shown). Specifically, the solder bump 160 layer can be coupled to (e.g., in contact with, bonded to) the wall 143 of the recess 144, the bottom surface 145 of the recess 144, the bottom surface of the protrusion 132, and/or a wall defining the opening 134 within the nonconductive layer 130.

FIG. 1B is a diagram that illustrates a top cross-sectional view of the portion of the chip scale package 100 shown in FIG. 1A. The top view of the portion of the chip scale package 100 illustrates the chip scale package 100 cut just above the plane C shown in FIG. 1A. The bottom surface of the protrusion 132 (just above the plane C) is shown in FIG. 1B. The edge of the wall 143 of the recess 144 (just below plane C) is shown in FIG. 1B as a dashed line.

In this embodiment, the opening 134 of the nonconductive layer 130 and the edge of the wall 143 of the recess 144 are shown as having a circular shape. In some embodiments, the opening 134 of the nonconductive layer 130 and/or the edge of the wall 143 of the recess 144 can have a different shape (or cross-sectional profile) such as a hexagonal shape, a square shape, a curved shape, an oval shape, a rectangular shape and/or so forth. In some embodiments, the opening 134 of the nonconductive layer 130 and the edge of the wall 143 of the recess 144 can have different shapes (or cross-sectional profiles).

As shown in FIG. 1B, the protrusion 132 extends over the recess 144. As shown in FIG. 1B, the recess 144 has a width E that is greater than a width D of the opening 134. In some embodiments, the width E of the recess 144 can be a maximum width of the recess 144, and the width D of the opening 134 can be a minimum width of the opening 134. In some embodiments, the width D and/or the width E can be between 50 μm and 500 μm (e.g., 100 μm, 175 μm, 220 μm, 400 μm). In some embodiments, the width D and/or the width E can be less than 50 μm or greater than 500 μm.

In some embodiments, the difference between width D and width E can be approximately between a few micrometers (e.g., 1 μm, 10 μm) and a few millimeters (e.g., 0.3 mm, 0.4, mm, 1 mm, 2 mm). In some embodiments, the difference between width D and width E can be less than a few micrometers or greater than a few millimeters. In some embodiments, the difference between the width D and width E can be approximately equal to a depth Q shown in FIG. 1A. In some embodiments, the difference between the width D and the width E can be greater than the depth Q, or less than the depth Q.

In some embodiments, the width D and/or the width E can be approximately between approximately 50% and 150% of a diameter of the solder bump 160 (shown in FIG. 1A). For example, the width D and/or the width E can be approximately 65% of the diameter of the solder bump 160. In some embodiments, the width D and/or the width E can be approximately 80% of the diameter of the solder bump 160. As another example, the width D and/or the width E can be approximately 105% of the diameter of the solder bump 160.

Referring back to FIG. 1A, in some embodiments, the wall 143 of the recess 144 may have a greater slope than that shown in FIG. 1A or may not be sloped (e.g., may be vertical or substantially vertical). In some embodiments, the wall 143 of the recess 144 may be sloped inward toward the opening 134 (from bottom to top) (e.g., smaller top width than bottom width) rather than away from the opening 134 (from bottom to top) as shown in FIG. 1A. In some embodiments, the bottom surface 145 of the recess 144 of the UBM layer 140 may be not be flat (e.g., may be curved or uneven). In some embodiments, the bottom surface 145 of the recess 144 can have a width (e.g., maximum width) that is greater than a width (e.g., minimum width) (shown as width D in FIG. 1B) of the opening 134.

As shown in FIG. 1A, the protrusion 132 has a triangular (or pointed) cross-sectional shape. In some embodiments, the protrusion 132 can have a different shape than a triangular cross-sectional shape. In other words, the walls defining the opening 134 can have a different profile than shown in FIG. 1A. For example, walls defining the opening 134 within the nonconductive layer 130 may be vertical (or substantially vertical). In such embodiments, the cross-sectional shape of the protrusion 132 may be substantially square, rectangular, curved, and/or so forth. In some embodiments, the protrusion 132 can define at least a portion of the profile of the opening 134. In some embodiments, the walls defining the opening 134 within the nonconductive layer 130 may be sloped inward from the bottom of the opening 134 (smaller top width than bottom width) toward the top of the opening 134 rather than away (from bottom to top) from the opening 134 as shown in FIG. 1A. In some embodiments, the walls defining the opening 134 can be curved, and/or so forth.

In some embodiments, at least a portion of the cavity 164, and the portion of the bottom portion 162 of the solder bump 160 disposed, therein can each have a triangular cross-sectional shape. In some embodiments, the cavity 164, and/or the portion of the bottom portion 162 of the solder bump 160 disposed therein, can have a different shape than a triangular (or pointed) cross-sectional shape. For example, the cavity 164, and the portion of the bottom portion 106 of the solder bump 160 disposed therein, can have a rectangular or square cross-sectional profile (if the wall 143 is not sloped).

Although not explicitly shown in FIG. 1A, an intermetallic layer can be formed at (or along) any of the interfaces between the solder bump 160 and the UBM layer 140. In some embodiments, an intermetallic layer can also be formed at (or along) any of the interfaces between the solder bump 160 and the nonconductive layer 130. Thus, an intermetallic layer can be formed along multiple surfaces. For example, an intermetallic layer can be formed along the wall 143 of the recess 144, along the bottom surface 145 of the recess 144, along the bottom surface of the protrusion 132 (aligned along plane C), and/or along a wall defining the opening 134 within the nonconductive layer 130. Thus, an intermetallic layer of the solder bump 160 can be formed along the wall 143 of the recess 144, the bottom surface of the protrusion 132, and/or along the bottom surface 145 of the recess 144, all of which are disposed below the plane C.

In some embodiments, the chip scale package 100 shown in FIG. 1A can define a package that is approximately the same size (or slightly larger than (e.g., up to ˜1.2 times larger than)) a die (formed from the semiconductor substrate 150). Thus, the portion of the chip scale package 100 may be (or define) a stand-alone discrete component that does not include, for example, a chip carrier such as a substrate or a lead frame, and/or molding around the semiconductor substrate 150. Although not shown, multiple solder bumps (similar to solder bump 160) can be coupled (e.g., coupled lateral to the solder bump 160) to the nonconductive layer 130 and/or to the metal layer 140. The pitch between the multiple solder bumps, in some embodiments, can be less than 1 millimeter (mm). In some embodiments, the pitch between the multiple solder bumps, in some embodiments, can be greater than or equal to 1 mm.

FIGS. 2A through 2E are cross-sectional diagrams that illustrate a method for producing a portion of a chip scale package 200 (e.g., the portion of the chip scale package 100 shown in FIG. 1A). In FIGS. 2A through 2E, various operations (e.g., semiconductor processing operations) are performed to form the portions of the chip scale package 200 (and other portions (not shown) of the chip scale package 200 lateral to the portion of the chip scale package 200 shown in FIGS. 2A through 2E).

FIGS. 2A through 2E are simplified diagrams that illustrate only some of the steps that may be required to form (e.g., produce, process) the portion of the chip scale package 200. In some embodiments, additional semiconductor processing operations (e.g., masking steps, etching steps, deposition steps, polishing steps) can be used to produce the portion of the chip scale package 200. In some embodiments, a die included in (or defining at least a portion of) the portion of the chip scale package 200 can have many semiconductor device (e.g., MOSFET devices) (which can be laterally oriented with respect to one another) and/or features similar to that shown in FIGS. 2A through 2D, dispersed throughout in a predefined pattern. For simplicity, numerals are generally shown on only one side of the portion of the chip scale package 200 in FIGS. 2A through 2E.

FIG. 2A is a cross-sectional diagram that illustrates the portion of the chip scale package 200 after an opening 234 has been formed in a nonconductive layer 230 disposed on an under bump metallization (UBM) layer 240 (which can be referred to as a conductive layer). The nonconductive layer 230 (which can be a passivation layer or an encapsulation layer) can include polyimide, PBO, BCB, silicon dioxide, silicon nitride, and/or so forth. The nonconductive layer 230 can be patterned to form the opening 234 through which the metal layer 240 can be accessed. The opening 234 can be formed within the nonconductive layer 230 using photolithography techniques. In other words, the opening 234 can be a photo-defined opening within the nonconductive layer 230. In some embodiments, the nonconductive layer 230 can include one or more layers formed using one or more different types of nonconductive material.

The UBM layer 240 can be deposited on a semiconductor substrate 250 that can include various semiconductor devices and/or features such as transistors (e.g., metal-oxide-semiconductor field effect transistors (MOSFETs), bipolar junction transistors (BJTs)), diodes, resistors, inductors, vias, metal layers, and/or so forth. In some embodiments, the UBM layer 240 can be formed using masking, etching, and/or deposition techniques. In some embodiments, the UBM layer 240 can be a seed layer, and the UBM layer 240 can be, or can include, various types of metal (or combinations thereof), such as, for example, copper (Cu), gold (Au), aluminum (Al), nickel (Ni), titanium (Ti), vanadium (V), platinum (Pt), and/or so forth. In some embodiments, the UBM layer 240 can be a patterned layer using, for example, etching techniques. In some embodiments, the UBM layer 240 can function as a solder diffusion barrier for inhibiting molten solder a solder bump 260 (which is formed later as shown in FIGS. 2D and 2E) from diffusing into the semiconductor substrate 250 and can function as a conductor to which the solder bump 260 can be coupled.

In some embodiments, the semiconductor substrate 250 may be included in (e.g., can be a part of) a silicon wafer during the processing of the UBM layer 240 and/or the nonconductive layer 230 (and/or the processing steps described below). In other words, the processing associated with the UBM layer 240 and/or the nonconductive layer 230 (and/or the processing steps described below) can be performed on a silicon wafer that includes the semiconductor substrate 250. In some embodiments, the semiconductor substrate 250 can be, or can include, various types of semiconductor processing techniques associated with semiconductor substrates including, but not limited to, for example, Silicon (Si), Germanium (Ge), Silicon Germanium (SiGe), Gallium Arsenide (GaAs), Silicon Carbide (SiC), type III-V semiconductor substrates, type II-VI semiconductor substrates, and/or so forth.

FIG. 2B is a diagram that illustrates formation of a recess 244 in the UBM layer 240. The recess 244 is formed in the UBM layer 240 using an etching process (also can be referred to as an etch process). In some embodiments, the recess 244 can be formed using an isotropic etching (e.g., wet etching) process. In some embodiments, various anisotropic etching techniques (e.g., reactive ion etching (RIE)) and/or isotropic etching techniques can be used to form the recess 244. The etching of the recess in the UBM layer 240 results in the formation of a protrusion 232 of the nonconductive layer 230, which extends over the recess 244 of the UBM layer 240. In other words, protrusion 232 of the nonconductive layer 230 remains after portions of the UBM layer 240 below the protrusion 232 are etched away. In some embodiments, the protrusion 232 of the nonconductive layer 230 can be referred to as an overhang.

In some embodiments, the etch process used to produce the stage shown in FIG. 2B can include a variety of chemistries. For example, the etch process can include based a sulfuric solution, a nitric acid solution, a citric acid solution, an ammonium per-sulfate solution, a cerium ammonium nitrate solution, and/or so forth. In some embodiments, one or more of these solutions can include peroxide. In some embodiments, the etch process can include a relatively dilute solution with between 50 to 1000 parts water to 1 part active material. The active material can include a combination of materials.

In some embodiments, a duration of the etch process can vary based on the chemistries used for the etch process. For example, the etch process can have a duration between approximately 1 minute and 20 minutes. In some embodiments, the etch process can have a duration of approximately 5 minutes, 10 minutes, etc. In some embodiments, the duration can be less than 1 minute or greater than 20 minutes. In some embodiments, the duration can depend on the etch chemistry, the target depth of the recess 244, the target width of the recess 244 and/or so forth.

In some embodiments, the recess 244 can have a depth F that can be approximately a fraction of a micrometer (e.g., 0.3 μm, 0.5 μm) to a few micrometers (e.g., 1 μm, 3 μm, 5 μm, 10 μm). In some embodiments, the depth F of the recess 244 can be a fraction of the thickness G of the UBM layer 240. In some embodiments, a ratio of the depth F of the recess 244 to the thickness G of the UBM layer 240 can be approximately between 1:100 to 1:2. In some embodiments, the thickness G can be approximately several micrometers (e.g., 5 μm, 10 μm, 15 μm). Similarly, a thickness I of the nonconductive layer 230 can be approximately several micrometers (e.g., 5 μm, 10 μm, 15 μm). In some embodiments, the thickness G of the UBM layer 240 can be approximately the same as the thickness I of the nonconductive layer. In some embodiments, the thickness G of the UBM layer 240 can be greater than, or less than, the thickness I of the nonconductive layer 230.

When the depth F of the recess 244 is formed using an isotropic etch, a length H of the protrusion 232 (that hangs over the recess 244) can be approximately the same as the depth F of the recess 244. Accordingly, the length H of the protrusion 232 can be approximately a fraction of a micrometer (e.g., 0.3 μm, 0.5 μm) to a few micrometers (e.g., 1 μm, 3 μm, 5 μm). In some embodiments, various anisotropic etching techniques and/or isotropic etching techniques can be used to form the recess 244. In such embodiments, the protrusion 232 can have a length H that is different from (e.g., shorter than) the depth F of the recess 244.

In some embodiments, the etching to produce the recess 244 in the UBM layer 240 can have a duration of between a few seconds (e.g., 20 seconds, 50 seconds) and several minutes (e.g., 2 min., 5 min., 10 min.). In some embodiments, the duration of the etching process to form the recess 244 can depend on the materials used to produce the UBM layer 240 and/or the etchant used in the etching process. In some embodiments, the duration of the etching process used to form the recess 244 can be significantly longer than a process used to prepare (e.g., clean) the surface of the UBM layer 240 before the solder bump 260 is coupled thereto.

As shown in FIG. 2B, the protrusion 232 and the recess 244 collectively define a cavity 246. Specifically, a wall of the recess 244 and a bottom surface of the protrusion 232 collectively define at least a portion of the cavity 246.

In some embodiments, the etching process can function as a pre-clean. In some embodiments, the etching process can clean organic materials, oxides (e.g., copper oxides), etc. from the nonconductive layer 230 and/or the UBM layer 240. In some embodiments, the etching process can clean one or more portions of the nonconductive layer 230 and/or the UBM layer 240.

FIG. 2C is a diagram that illustrates formation of a flux layer 270 on the nonconductive layer 230 and the UBM layer 240. The flux layer 270 can be disposed on the nonconductive layer 230 and the UBM layer 240 through a mesh (e.g., a pre-fabricated screen). As shown in FIG. 2C, the flux layer 270 is disposed within the opening 234 in the nonconductive layer 230 and within the recess 244 of the UBM layer 240.

In some embodiments, the flux layer 270 can have a width R that is larger than a diameter of a solder bump to be disposed on the flux layer 270. The flux layer 270 can be a flowing agent configured to facilitate adhesion of the solder bump to the nonconductive layer 230 and/or to the UBM layer 240. The flux layer 270 can be, for example, a water soluble flux, a no-clean flux, an epoxy flux, and/or so forth. In some embodiments, the flux layer 270 can include one or more layers that each include one or more different types of flux material.

FIG. 2D is a diagram that illustrates a solder bump 260 disposed within the opening 234 of the nonconductive layer 230 before a reflow process has been performed. As shown in FIG. 2D, the solder bump 260 is outside of the cavity 246 (and/or other portions of the recess 244) when the solder bump 260 is disposed within the opening before reflow has been performed. Although the solder bump 260 shown in FIG. 2D has a spherical shape, and some embodiments, the solder bump 260 may not have a spherical shape. For example, at least a portion of the solder bump 260 may have a flat surface. As discussed above, in some embodiments, the solder bump 260 can be formed using various materials (or combinations thereof) including silver (Ag), tin (Sn), copper (Cu), Nickel (Ni), and/or so forth (e.g., SAC, SNC, SACX, and other tin (Sn) based alloys).

FIG. 2E is a diagram that illustrates the solder bump 260 disposed within the opening 234 of the nonconductive layer 230 after a reflow process has been performed. After the reflow process has been performed, a portion 263 of the solder bump 260 within the recess 244 is disposed within the cavity 246. The portion 263 of the solder bump 260 has an upper surface that is coupled to (or in contact with) a bottom surface of the protrusion 232. In some embodiments, the reflow process can be a relatively high temperature reflow process that melts the solder bump 260 and causes the portion 263 of the solder bump 260 to fill the cavity 246.

In some embodiments, the temperature reflow process can vary between, for example, 50° C. and 500° C. (e.g., 250° C.), and a duration of the reflow process can vary between a few minutes and a few hours (e.g., 10 min., 20 min.). The temperature and/or duration of the reflow process can vary depending on the chemistry of the solder bump 260, the chemistry of the flux layer (shown in FIGS. 2C and 2D), the size of the recess 244 and/or the cavity 246, and/or so forth.

The flux layer 270 shown in FIGS. 2C and 2D can facilitate in the reflow process and filling of the cavity 246 by the melted solder bump 260. During the reflow process, the flux layer 270 can melt and/or evaporate. Although not shown, in some embodiments, the flux layer 270 can be made of a material that does not entirely melt and/or evaporate. In such embodiments, the flux layer 270 can form a collar around at least a portion of the solder bump 260.

By forming the recess 244 and the cavity 246, a surface area to which the solder bump 260 may adhere can be greater than without the recess 244 and/or the cavity 246. This can be visually observed by comparing FIG. 2A, which excludes the recess 244 and the cavity 246, with FIG. 2B, which includes the recess 244 and the cavity 246. The increased surface area can facilitate adhesion of the solder bump 260 to the UBM layer 240 and/or to the nonconductive layer 230.

In some embodiments, during the reflow process an intermetallic layer (not shown) can be formed. In some embodiments at least a portion of the intermetallic layer can be formed at any interface between the bulk of the solder bump 260 and at least a portion of the UBM layer 240 and/or at least a portion of the nonconductive layer 230.

In some embodiments, rather than using a reflow process, the solder bump 260 (or a variation thereof) can be formed using a plating technique. The plating technique may include depositing one or more barrier and/or seed layers, photo masking, solder plating, resist strip, and/or so forth.

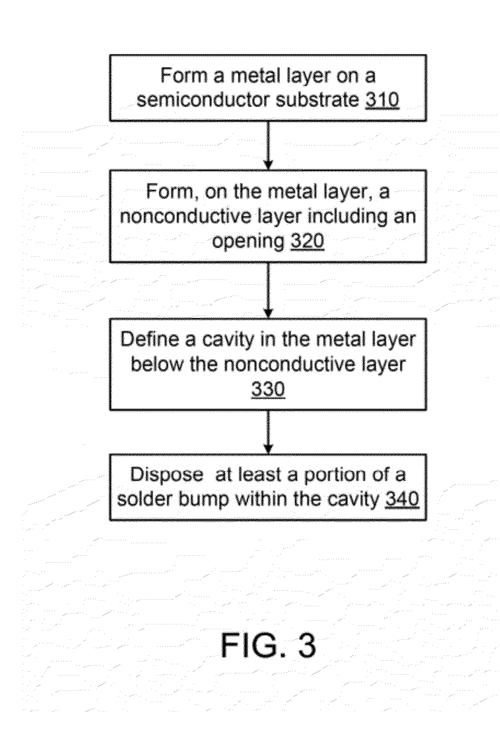

FIG. 3 is a flowchart that illustrates a method for forming a portion of a chip scale package, according to an embodiment. The portion of the chip scale package can be similar to the portions of the chip scale packages described above (e.g., the portion of the chip scale package 100 shown in FIG. 1).

A metal layer is formed on a semiconductor substrate (block 310). The metal layer can be deposited on the semiconductor substrate using one or more deposition techniques. In some embodiments, the metal layer can be an under bump metallic (UBM) layer. Various types of semiconductor devices (e.g., MOSFET devices) and/or other features (e.g., trenches, pads, etc.) can be formed within the semiconductor substrate before the metal layer is formed on the semiconductor substrate. In some embodiments, the metal layer can include a material such as copper.

A nonconductive layer including an opening is formed on the metal layer (block 320). In some embodiments, the nonconductive layer can be photo-defined on the metal layer. In some embodiments, different types of nonconductive layers can be formed on the metal layer such as a polyimide layer. In some embodiments, the opening can have sloped walls or can have vertical walls. The opening can be defined so that at least a portion of a solder bump can be placed within the opening. The opening can be defined over a portion of the metal layer to which a solder bump may be coupled.

At least a portion of a cavity is defined in the metal layer below the nonconductive layer (block 330). The portion of the cavity can be defined in the metal layer using an isotropic etching process as portions of the metal layer are etched away from underneath the nonconductive layer. In some embodiments, a top portion of the cavity (e.g., crevice) can be defined by a bottom surface of (e.g., a bottom surface of a protrusion of) the nonconductive layer.

At least a portion of a solder bump is disposed within the cavity (block 340). In some embodiments, the portion of the solder bump can be disposed within the cavity using a relatively high temperature reflow process. In some embodiments, during the reflow process an intermetallic layer (by migration of metals within the solder bump) can be formed. In some embodiments at least a portion of the intermetallic layer can be at an interface between the bulk of the solder bump and at least a portion of the metal layer and/or at least a portion of the nonconductive layer. In some embodiments, at least a portion of the intermetallic layer can be disposed within a layer (e.g., within the recess of the UBM layer) below the nonconductive layer (e.g., below a plane aligned along the nonconductive layer). Although not shown in FIG. 3, in some embodiments, the method can include forming one or more flux layers before the solder bump is disposed within the cavity.

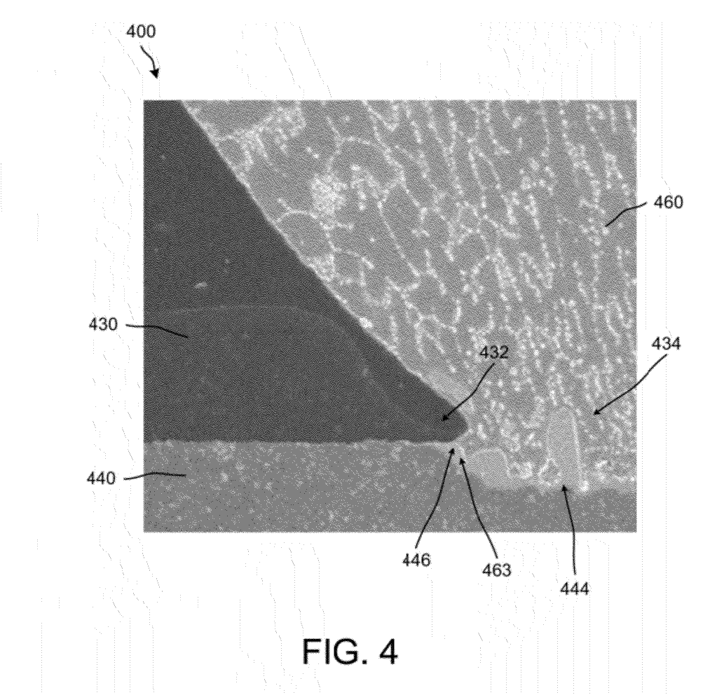

FIG. 4 is a scanning electron microscopic (SEM) image of a cross-sectional portion of a chip scale package 400, according to an embodiment. The portion of the chip scale package 400 shown in FIG. 4 can be a wafer-level chip scale package (WLCSP). The solder bump 460 is coupled to a nonconductive layer 430 (which can also be referred to as an encapsulating layer) and an under bump metallization (UBM) layer 440. The UBM layer 440 is disposed on a semiconductor substrate (not shown). The semiconductor substrate 450 can include various semiconductor devices and/or features such as transistors (e.g., metal-oxide-semiconductor field effect transistors (MOSFETs), bipolar junction transistors (BJTs)), diodes, resistors, inductors, vias, metal layers, and/or so forth. Many of the features shown in FIG. 4 are mirrored within another portion (not shown) of the chip scale package 400.

As shown in FIG. 4, the solder bump 460 is coupled to the UBM layer 440 through an opening 434 within the nonconductive layer 430. Specifically, the solder bump 460 has a bottom portion disposed within a recess 444 (also can be referred to as a pocket) defined by the UBM layer 440. As shown in FIG. 4, a protrusion 432 of the nonconductive layer 430 and the recess 444 collectively define a cavity 446 (or crevice). A portion 463 of the solder bump 460 within the recess 444 is disposed within the cavity 446. In some embodiments, the portion 463 of the solder bump 460 can be disposed within the cavity 446 during a reflow process of the solder bump 460. The protrusion 432 of the nonconductive layer 430 can function as a retention member configured to reliably hold the solder bump 460 fast (without lifting) within the portion of the chip scale package 400 during reliability testing and/or during use within a computing application.

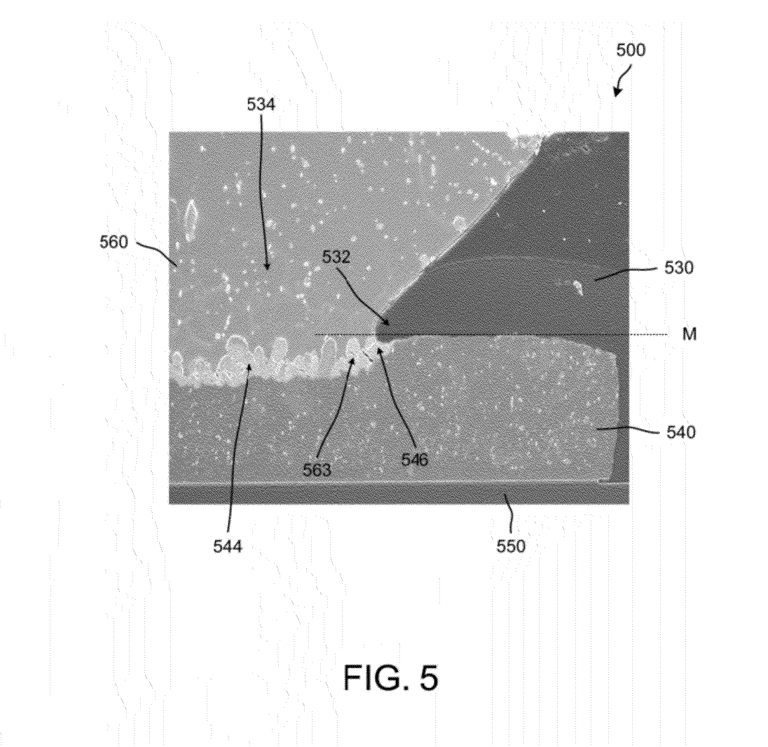

FIG. 5 is another SEM image of a cross-sectional portion of a chip scale package 500, according to an embodiment. The portion of the chip scale package 500 shown in FIG. 5 can be a wafer-level chip scale package (WLCSP). The solder bump 560 is coupled to a nonconductive layer 530 (which can also be referred to as an encapsulating layer) and an under bump metallization (UBM) layer 540. The UBM layer 540 is disposed on a semiconductor substrate 550. The semiconductor substrate 550 can include various semiconductor devices and/or features such as transistors (e.g., metal-oxide-semiconductor field effect transistors (MOSFETs), bipolar junction transistors (BJTs)), diodes, resistors, inductors, vias, metal layers, and/or so forth. Many of the features shown in FIG. 5 are mirrored within another portion (not shown) of the chip scale package 500.

As shown in FIG. 5, the solder bump 560 is coupled to the UBM layer 540 through an opening 534 within the nonconductive layer 530. Specifically, the solder bump 560 has a bottom portion disposed within a recess 544 (also can be referred to as a pocket) defined by the UBM layer 540. As shown in FIG. 5, a protrusion 532 of the nonconductive layer 530 and the recess 544 collectively define a cavity 546 (or crevice). A portion 563 of the solder bump 560 within the recess 544 is disposed within the cavity 546. In some embodiments, the portion 563 of the solder bump 560 can be disposed within the cavity 546 during a reflow process of the solder bump 560. The protrusion 532 of the nonconductive layer 530 can function as a retention member configured to reliably hold the solder bump 560 fast (without lifting) within the portion of the chip scale package 500 during reliability testing and/or during use within a computing application.

As shown in FIG. 5, the protrusion 532 of the nonconductive layer 530 has a portion that is disposed below (e.g., extends below) a horizontal plane M. The protrusion 532 has a portion that curves below the horizontal plane M. The horizontal plane M is approximately aligned along an interface between the nonconductive layer 530 and the UBM layer 540. The profile of the protrusion 532 shown in FIG. 5 is contrasted with a profile of protrusion 432 shown in FIG. 4, which does not have a portion that is disposed below the plane aligned along the interface between the nonconductive layer 430 and the UBM layer 540.

In one general aspect, an apparatus can include a semiconductor substrate including at least one semiconductor device, and a metal layer disposed on the semiconductor substrate. The apparatus can include a nonconductive layer defining an opening and having a cross-sectional portion of the nonconductive layer defining a protrusion disposed over a recess in the metal layer, and can include a solder bump having a portion disposed between the metal layer and the protrusion defined by the nonconductive layer.

In some embodiments, an interface between the nonconductive layer and the metal layer are aligned along a plane, and the protrusion has a bottom portion aligned along the plane and the portion of the solder bump is aligned along the plane. In some embodiments, the portion of the solder bump has an upper surface coupled to a bottom portion of the protrusion of the nonconductive layer.

In some embodiments, the semiconductor substrate, the metal layer, the nonconductive layer, and the solder bump collectively define at least a portion of a chip scale package. In some embodiments, the protrusion is formed using an isotropic etching process. In some embodiments, the portion of the solder bump disposed between the metal layer and the protrusion defined by the nonconductive layer has a triangular cross-sectional shape. In some embodiments, the protrusion has a triangular cross-sectional shape.

In another general aspect, a method can include forming a metal layer on a semiconductor substrate, and forming, on the metal layer, a nonconductive layer including an opening. The method can include defining at least a portion of a cavity aligned within the opening and in the metal layer below the nonconductive layer. The method can also include disposing at least a portion of a solder bump within the cavity.

In some embodiments, the defining of the cavity is performed using an isotropic etch process. In some embodiments, the portion of the solder bump is disposed within the cavity using a reflow process. In some embodiments, the method can include heating the solder bump until the at least the portion of the solder bump is coupled to a bottom surface of the nonconductive layer that protrudes over the cavity.

In some embodiments, the defining includes defining a protrusion over the cavity from the nonconductive layer. In some embodiments, the portion of the solder bump is disposed within the cavity using a reflow process. The method can also include forming a flux layer over the opening included in the nonconductive layer and over the cavity, and disposing at least a portion of the solder bump on the flux layer before the solder bump is disposed within the cavity using reflow process.

In yet another general aspect, an apparatus can include a semiconductor substrate including at least one semiconductor device, and a nonconductive layer defining an opening. The apparatus can include a metal layer disposed between the semiconductor substrate and a nonconductive layer. The metal layer can define a recess having a portion disposed below the opening and having a portion with a width greater than a width of a portion of the opening of the nonconductive layer aligned along an interface between the metal layer and the nonconductive layer.

In some embodiments, the apparatus can include a solder bump disposed within the recess and having a portion coupled to the metal layer and the nonconductive layer. In some embodiments, the apparatus can include a solder bump disposed within the recess and having a portion coupled to a bottom surface of the nonconductive layer that extends over at least a portion of the recess in the metal layer.

In some embodiments, the opening of the nonconductive layer is defined by a sloped wall, the recess is defined, at least in a part, by a sloped wall. In some embodiments, the recess has a sloped wall disposed below at least a portion of a sloped wall of the opening of the nonconductive layer. In some embodiments, the interface between the nonconductive layer and the metal layer are aligned along a plane, and the portion of the recess and the portion of the opening are aligned along the plane.

In some embodiments, the an interface between the nonconductive layer and the metal layer are aligned along a plane. The apparatus can include an intermetallic layer included in a portion of a solder bump disposed below the plane within the recess. In some embodiments, the recess has a maximum width greater than a minimum width of the opening. In some embodiments, a difference between the width of the recess and the width of the opening is greater than 0.5 microns.

Implementations of the various techniques described herein may be implemented in digital electronic circuitry, or in computer hardware, firmware, software, or in combinations of them. Some implementations may be implemented using various semiconductor processing and/or packaging techniques. As discussed above, some embodiments may be implemented using various types of semiconductor processing techniques associated with semiconductor substrates including, but not limited to, for example, Silicon (Si), Gallium Arsenide (GaAs), Silicon Carbide (SiC), type III-V semiconductor substrates, type II-VI semiconductor substrates, and/or so forth. and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. An apparatus, comprising:
a semiconductor substrate including at least one semiconductor device;
a metal layer disposed on the semiconductor substrate;
a nonconductive layer defining an opening and having a cross-sectional portion of the nonconductive layer defining a protrusion over a recess in the metal layer; and
a solder bump having a portion disposed between the metal layer and the protrusion defined by the nonconductive layer.

2. The apparatus of claim 1, wherein an interface between the nonconductive layer and the metal layer are aligned along a plane, the protrusion has a bottom portion aligned along the plane and the portion of the solder bump is aligned along the plane.

3. The apparatus of claim 1, wherein the portion of the solder bump has an upper surface coupled to a bottom portion of the protrusion of the nonconductive layer.

4. The apparatus of claim 1, wherein the semiconductor substrate, the metal layer, the nonconductive layer, and the solder bump collectively define at least a portion of a chip scale package.

5. The apparatus of claim 1, wherein the protrusion is formed using an isotropic etching process.

6. The apparatus of claim 1, wherein the portion of the solder bump disposed between the metal layer and the protrusion defined by the nonconductive layer has a triangular cross-sectional shape.

7. The apparatus of claim 1, wherein the protrusion has a triangular cross-sectional shape.

8. A method, comprising:
forming a metal layer on a semiconductor substrate;
forming, on the metal layer, a nonconductive layer including an opening;
defining at least a portion of a cavity aligned within the opening and in the metal layer below the nonconductive layer; and
disposing at least a portion of a solder bump within the cavity.

9. The method of claim 8, wherein the defining of the cavity is performed using an isotropic etch process.

10. The method of claim 8, wherein the portion of the solder bump is disposed within the cavity using a reflow process.

11. The method of claim 8, further comprising:
heating the solder bump until the at least the portion of the solder bump is coupled to a bottom surface of the nonconductive layer that protrudes over the cavity.

12. The method of claim 8, wherein the defining includes defining a protrusion over the cavity from the nonconductive layer.

13. The method of claim 8, wherein the portion of the solder bump is disposed within the cavity using a reflow process,
the method, further comprising:
forming a flux layer over the opening included in the nonconductive layer and over the cavity; and
disposing at least a portion of the solder bump on the flux layer before the solder bump is disposed within the cavity using reflow process.

14. An apparatus, comprising:
a semiconductor substrate including at least one semiconductor device;
a nonconductive layer defining an opening; and
a metal layer disposed between the semiconductor substrate and a nonconductive layer, the metal layer defining a recess having a portion disposed below the opening and having a portion with a width greater than a width of a portion of the opening of the nonconductive layer aligned along an interface between the metal layer and the nonconductive layer.

15. The apparatus of claim 14, further comprising:
a solder bump disposed within the recess and having a portion coupled to the metal layer and the nonconductive layer.

16. The apparatus of claim 14, further comprising:
a solder bump disposed within the recess and having a portion coupled to a bottom surface of the nonconductive layer that extends over at least a portion of the recess in the metal layer.

17. The apparatus of claim 14, wherein the opening of the nonconductive layer is defined by a sloped wall, the recess is defined, at least in a part, by a sloped wall.

18. The apparatus of claim 14, wherein the recess has a sloped wall disposed below at least a portion of a sloped wall of the opening of the nonconductive layer.

19. The apparatus of claim 14, wherein the interface between the nonconductive layer and the metal layer are aligned along a plane, the portion of the recess and the portion of the opening are aligned along the plane.

20. The apparatus of claim 14, wherein an interface between the nonconductive layer and the metal layer are aligned along a plane,
the apparatus further comprising:
an intermetallic layer included in a portion of a solder bump disposed below the plane within the recess.

21. The apparatus of claim 14, wherein the recess has a maximum width greater than a minimum width of the opening.

22. The apparatus of claim 14, wherein a difference between the width of the recess and the width of the opening is greater than 0.5 microns.
